(19) United States
(12) Patent Application Publication
(10) Pub. No.: US 2010/0248418 A1
(43) Pub. Date: Sep. 30, 2010

(54) PHOTOELECTRIC CONVERTER, AND TRANSPARENT CONDUCTIVE SUBSTRATE FOR THE SAME

(75) Inventors: Masahiro Morooka, Kanagawa (JP); Yusuke Suzuki, Kanagawa (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 12/815,718

(22) Filed: Jun. 15, 2010

Related U.S. Application Data
(62) Division of application No. 11/579,976, filed on Aug. 31, 2007.

(30) Foreign Application Priority Data
May 14, 2004 (JP) JP2004-144618

(51) Int. Cl. H01L 31/18

(52) U.S. Cl. 438/85; 257/E31.001

(57) ABSTRACT

A highly durable photoelectric converter with excellent photoelectric conversion efficiency is prevented from resistance loss or lowering of photoelectric conversion efficiency and free from problems of corrosion and reverse electron transfer reaction. Specifically disclosed is a photoelectric converter (1) comprising a semiconductor electrode (11), a counter electrode (12), and an electrolyte layer (5) arranged between the electrodes. The semiconductor electrode (11) includes a transparent conductive substrate (10) including a transparent base (2), a conductive interconnection layer (3), and a metal oxide layer (30), and a semiconductor particle layer (4) arranged on the transparent conductive substrate (10). The transparent base (2) of the transparent conductive substrate (10) has a trench (3h) on one surface, and the conductive interconnection layer (3) is embedded in this trench (3h).

### TECHNICAL FIELD

The present invention relates to photoelectric converters, and transparent conductive substrates for the same.

### BACKGROUND ART

Fossil fuels such as coal and petroleum, if used as energy sources, form carbon dioxide which is believed to cause global warming.

Nuclear energy, if used, may be at risk for radioactive contamination.

Continuous full dependence on such conventional energy will cause various global or local environmental issues.

In contrast, solar cells affect the global environment very slightly and are expected to become widespread further more. This is because solar cells are photoelectric converters that use sunlight as an energy source and convert sunlight into electrical energy.

For example, various solar cells using silicon as a material are commercially available, and these are broadly divided into crystalline silicon solar cells using single-crystal silicon or polycrystalline silicon, and amorphous silicon solar cells.

Most of conventional solar cells use single-crystal or polycrystalline silicon.

These crystalline silicon solar cells, however, require much energy and time for growing their crystals, thereby have low productivity and are disadvantageous in cost, although they show a higher conversion efficiency than that of amorphous silicon. The conversion efficiency herein indicates the performance for converting light (sunlight) energy into electrical energy.

In contrast, amorphous silicon solar cells have higher optical absorptivity, have wider selectivity of substrates, can be more easily increased in area, and thereby have higher productivity than crystalline silicon solar cells, although they show a lower conversion efficiency than crystalline silicon solar cells. Amorphous silicon solar cells, however, require vacuum processes, and this is still a large burden on facilities.

For further cost reduction, investigations have been made on solar cells using organic materials instead of silicon. However, solar cells of this type have a very low photoelectric conversion efficiency of 1% or less and show poor durability.

Under these circumstances, a solar cell using porous fine semiconductor particles sensitized by a dye, thereby having an improved conversion efficiency and showing lower cost has been reported (see, for example, Nature (353, p.737-740, 1991)).

This solar cell is a wet solar cell using a porous thin titanium oxide film as a photoelectrode, which thin film is spectrally sensitized by the action of a ruthenium complex as a sensitizing dye. In other words, it is an electrochemical photovoltaic cell.

This solar cell is advantageous in that it can use inexpensive oxide semiconductors such as titanium oxide; the sensitizing dye can absorb light at broad-range visible wavelengths up to 800 nm; and the solar cell has a high quantum efficiency in photoelectric conversion and realizes a high energy conversion efficiency. In addition, the solar cell can be produced without a vacuum process and does not require, for example, large-sized facilities.

To realize higher outputs of photoelectric converters such as solar cells, the converters must have larger sizes. However, current commercially available transparent conductive substrates, if used for the production of large-area photoelectric converters, have a high surface electrical resistance and cannot significantly realize a satisfactory photoelectric conversion efficiency due to loss in fill factor.

To avoid these problems, transparent conductive substrates for use in the production of large-area photoelectric converters must have a reduced surface electrical resistance. A possible candidate for this is a configuration as shown, for example, in a schematic diagram of FIG. 5 illustrating a semiconductor electrode in a photoelectric converter. Specifically, the semiconductor electrode 111 comprises a transparent base 102 and a metal oxide layer 108 arranged adjacent to the transparent base 102 and further comprises a conductive interconnection layer 103 arranged adjacent to the metal oxide layer 108. The conductive interconnection layer 103 has an interconnection pattern formed from a conductive metal or carbon.

This configuration, however, shows significantly deteriorated properties with elapse of time. This is because an electrolyte layer 105 arranged between electrodes of the photoelectric converter comprises an electrolyte solution containing a halogen element such as iodine; and the electrolyte solution, if it reaches a conductive interconnection layer 103 through a semiconductor particle layer 104, invites the dissolution and break of interconnection due to corrosion and/or the fracture of interconnection due to dissolution of the underlayer metal.

A possible solution to these problems is a technic of applying a metal material having high corrosion resistance as a material for the conductive interconnection layer 103. Even according to this technique, however, deterioration in properties of a photoelectric converter cannot be fully avoided when the photoelectric converter has such a configuration that the conductive interconnection layer 103 is in direct contact with the electrolyte solution. This is because a reverse electron transfer reaction occurs in which electrons reaching the conductive interconnection layer reduce the electrolyte before they flow into an external circuit.

To avoid these problems, a possible solution is a modified layer configuration of the photoelectric converter. Specifically, the transparent conductive substrate 110 of this modified configuration has a multilayer structure of a transparent base 102, a conductive interconnection layer 103, and a metal oxide layer 108 arranged in this order from the receiving surface.

According to this configuration, the above-mentioned corrosion and reverse electron transfer reaction can be suppressed when the conductive interconnection layer 103 has a very small thickness, because the conductive interconnection layer 103 can be sufficiently covered with the metal oxide layer 108 arranged as its upper layer.

Such a very thin conductive interconnection layer 103, however, acts to increase the electrical resistance to thereby increase the resistance loss, and this results in a decreased photoelectric conversion efficiency.

When the conductive interconnection layer 103 has a thickness of, for example, 0.5 μm or more in view of ensuring practical functions, a side slope of the conductive interconnection layer 103 may not be fully covered by the metal oxide layer 108. The electrolyte solution penetrates such an uncovered region and causes corrosion and reverse electron transfer reaction.

Accordingly, an object of the present invention is to provide a highly durable photoelectric converter with excellent photoelectric conversion efficiency which is prevented from resistance loss or lowering of photoelectric conversion efficiency and free from problems of corrosion and reverse electron transfer reaction, regardless of the film thickness of the conductive interconnection layer 103. Another object of the present invention is to provide a transparent conductive substrate for use therein.

### DISCLOSURE OF INVENTION

The present invention provides a photoelectric converter comprising a semiconductor electrode, a counter electrode, and an electrolyte layer arranged between the semiconductor electrode and the counter electrode, the semiconductor electrode comprising a transparent conductive substrate and a semiconductor particle layer arranged adjacent to the transparent conductive substrate, the transparent conductive substrate comprising a transparent base, a conductive interconnection layer, and a metal oxide layer, in which the transparent base of the transparent conductive substrate has a trench in its surface facing the semiconductor particle layer, and the conductive interconnection layer is embedded in the trench.

The present invention further provides a transparent conductive substrate for constituting an electrode of a photoelectric converter, comprising a transparent base, a conductive interconnection layer, and a metal oxide layer, in which the transparent base has a trench on its principal plane and the conductive interconnection layer is embedded in the trench.

The present invention dramatically improves the photoelectric conversion efficiency by arranging a conductive interconnection layer in an electrode. In addition, it provides a highly durable transparent conductive substrate with excellent photoelectric conversion efficiency which is prevented from resistance loss or lowering of photoelectric conversion efficiency and free from problems of corrosion and reverse electron transfer reaction; and a photoelectric converter having the transparent conductive substrate, by embedding the conductive interconnection layer in a transparent base.

### BRIEF DESCRIPTION OF THE DRAWINGS

FIG. 1 is a schematic diagram of a photoelectric converter according to the present invention.

FIG. 2 is a schematic diagram of a transparent conductive substrate constituting the photoelectric converter.

FIG. 3 is a schematic plan view illustrating the formation of a conductive interconnection layer.

FIG. 4 is a schematic cross-sectional view illustrating the formation of the conductive interconnection layer.

FIG. 5 is a schematic diagram of a principal part of a conventional photoelectric converter.

### BEST MODE FOR CARRYING OUT THE INVENTION

Specific embodiments of the present invention will be illustrated below with reference to the attached drawings, but it should be noted that the followings are illustrated only by example and never intended to limit the scope of the present invention.

The photoelectric converter according to the present invention will be mainly illustrated below, in combination with a semiconductor electrode and a transparent conductive substrate as components of the photoelectric converter.

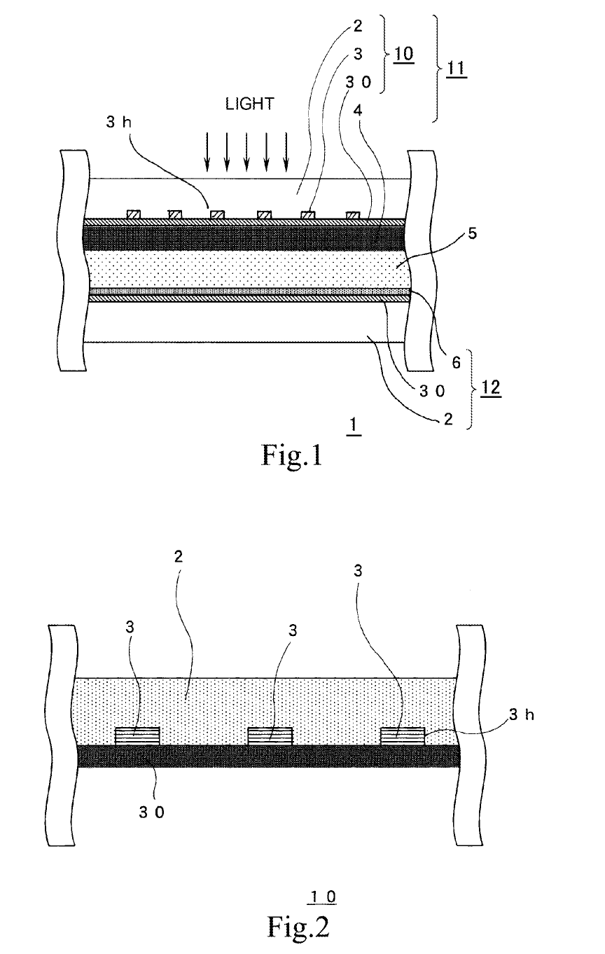

FIG. 1 is a schematic diagram of a photoelectric converter 1 as an embodiment of the present invention.

The photoelectric converter 1 comprises a semiconductor electrode 11, a counter electrode 12, and an electrolyte layer 5 held between them.

The semiconductor electrode 11 has a multilayer structure comprising a transparent conductive substrate 10 and a semiconductor particle layer 4 arranged adjacent to the transparent conductive substrate 10. The transparent conductive substrate 10 comprises a transparent base 2, a conductive interconnection layer 3, and a metal oxide layer 30.

The counter electrode 12 has a multilayer structure comprising a transparent base 2, a metal oxide layer 30, and a platinum layer 6. The counter electrode 12 may further comprise a conductive interconnection layer 3 in the transparent base, as in the semiconductor electrode 11.

The photoelectric converter 1 is so configured that light is applied from the semiconductor electrode 11.

The semiconductor electrode 11 will be illustrated below.

The transparent base 2 is not specifically limited and can be a conventional transparent base used in semiconductor electrodes.

The transparent base 2 is preferably excellent in barrier property against external moisture and gas, chemical resistance, and weather resistance. Specific examples thereof include transparent inorganic bases such as quartz, sapphire, and glass; and transparent plastic bases such as poly(ethylene terephthalate)s, poly(ethylene naphthalate)s, polycarbonates, polystyrenes, polyethylenes, polypropylenes, poly(phenylene sulfide)s, poly(vinylidene fluoride)s, tetraacetyl cellulose, brominated phenoxy, aramids, polyimides, polystyrenes, polyallylates, polysulfones, and polyolefins. The transparent base 2 especially preferably comprises a material having high transmittance of light at visible wavelengths.

FIG. 2 is a schematic diagram of the transparent conductive substrate 10 according to the present invention.

The transparent conductive substrate 10 comprises a transparent base 2, a conductive interconnection layer 3, and a metal oxide layer 30 arranged in this order from the receiving surface of the photoelectric converter 1. This has a structure in which the transparent base 2 has a linear or grid-shaped trench 3h in its surface facing the semiconductor particle layer, and the conductive interconnection layer 3 is embedded in the trench 3h.

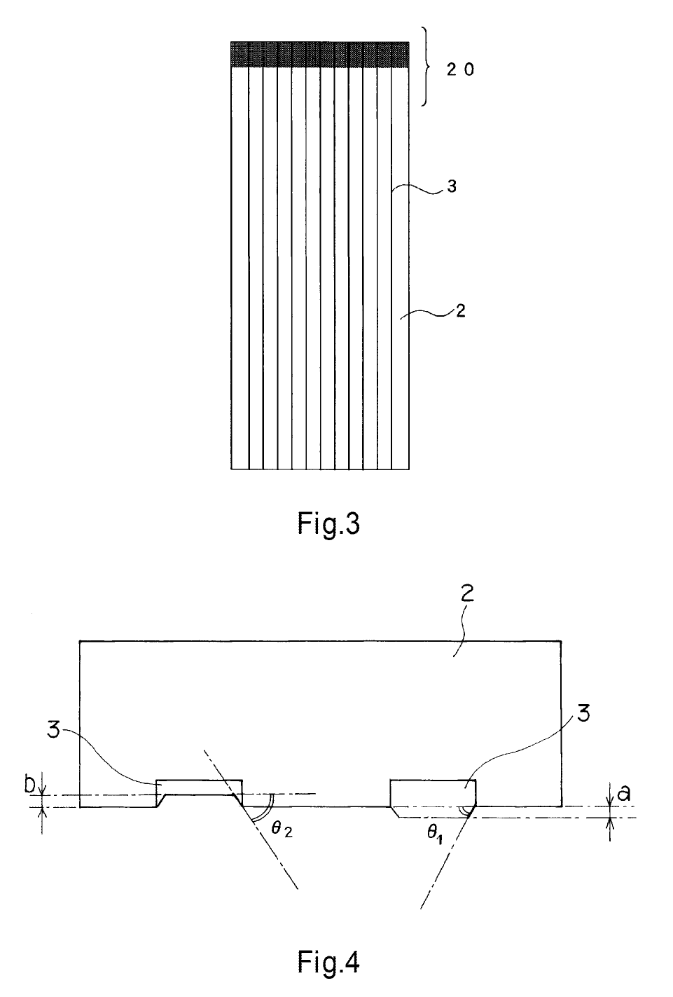

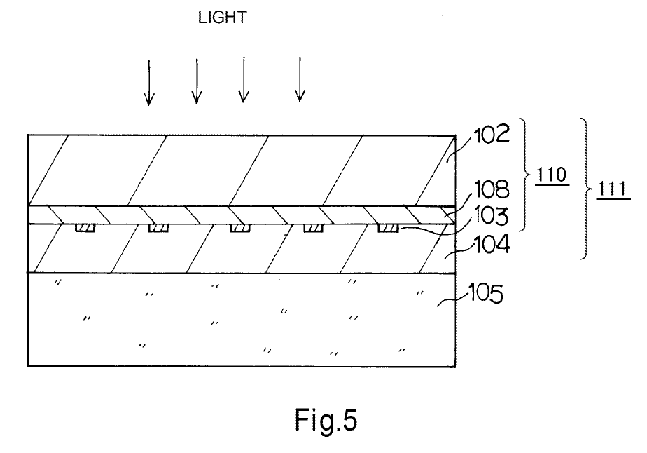

FIG. 3 is a schematic plan view in which the transparent base 2 has linear trenches, and the conductive interconnection layer 3 is embedded in the trenches.

The term “transparent” herein is defined as that the transparency is 10% or more with respect to part or all of light in visible to near-infrared regions at 400 nm to 1200 nm.

The conductive interconnection layer 3 can be embedded in the transparent base 2, for example, by a process of forming convex and concave portions for interconnection in the transparent base 2 in advance, and depositing a film of a conductive interconnection layer in the convex and concave portions; or a process of a metal interconnection in the transparent base 2 by welding, and exposing the metal interconnection by polishing.

Trenches (convex and concave portions) for the formation of the conductive interconnection layer can be formed in the transparent base 2 according to a conventional process. Examples of such processes are a process of forming linear trenches using a slicing machine or a diamond cutter; a process of laminating bases by optical welding; a process using etching and template. Among them, the process using a slicing machine is an easy and convenient process.

The conductive interconnection layer 3 preferably comprises, as a material, a substance having high electron conductivity, and more preferably an electrochemically stable substance. It preferably comprises at least one conductive material selected from the group consisting of metals, alloys, and conductive polymers.

FIG. 4 is an enlarged schematic cross-sectional view of the conductive interconnection layer 3 formed in the transparent base 2.

The angles (θ1 and θ2 in FIG. 4) made between the side of the conductive interconnection layer 3 and the plane of the transparent base 2 are preferably less than 60° both in convex portion and concave portion with reference to the transparent base plane)(0°.

When the angles (θ1 and θ2) made between the conductive interconnection layer 3 and the transparent base plane are 60° or more, it is difficult for the metal oxide layer 30 arranged as an upper layer thereof to fully cover the inclined sides, and this causes direct contact of the electrolyte solution in the electrolyte layer with the conductive interconnection layer 3 to thereby cause deterioration due to corrosion and reverse electron transfer reaction.

The conductive interconnection layer 3 preferably has a difference (“a” and “b” in FIG. 4) in height or depth between its highest or deepest point and the transparent base plane of within 10 μm or less both in convex portion and concave portion, with reference to the transparent base plane (0°). Specifically, assuming that “a” is greater than 0 and “b” is less than 0, the height of the highest (or deepest) plane or point of the conductive interconnection layer 3 is preferably −10 μm or more and 10 μm or less with reference to the transparent base plane.

If the difference in height between the conductive interconnection layer 3 and the transparent base plane is large, the metal oxide layer 30 arranged as an upper layer thereof may often have irregularity, the electrolyte solution of the electrolyte layer may penetrate through resulting pinholes and cracks and cause corrosion of the conductive interconnection layer 3 and invites the reverse electron transfer reaction.

The thickness of the conductive interconnection layer 3 is preferably about 0.1 μm to about 100 μm for sufficient reduction in resistance loss.

The process for forming the conductive interconnection layer 3 in the transparent base 2 is not specifically limited but is preferably a wet film deposition process.

For example, it can be deposited by electroless plating of various metals or alloys; printing or coating, spin coating, dip coating, or spray coating using a paste; and any other processes. Among them, electroless plating is preferred as a process for deposing a uniform film having low electrical resistance.

Applicable processes also include welding of a low melting alloy using an ultrasonic soldering machine; and dry film deposition processes such as vapor deposition, ion plating, sputtering, and chemical vapor deposition (CVD); and any other known processes.

A predetermined underlayer may be arranged so as to improve the adhesion of the conductive interconnection layer 3 with the transparent base 2. Annealing can be carried out for improving the crystallinity and reducing the electrical resistance.

The process for exposing the conductive interconnection layer 3 from the film deposition plane so as to have a suitable film thickness can be any conventional process such as polishing typically by buffing, sand blasting, or lapping; etching; or lithography.

The area ratio of the conductive interconnection layer 3 to the receiving surface of the photoelectric converter is not specifically limited but is preferably 0.01% to 70%.

The area ratio of the conductive interconnection layer 3 is more preferably 0.1% to 50%, because if it is excessively large, the received light may not be sufficiently transmitted.

The width of and intervals between lines of the resulting conductive interconnection layer 3 are not specifically limited, but the resistance loss of the transparent conductive substrate 10 can be more effectively reduced with an increasing width and decreasing intervals.

In contrast, the transmittance of the incident light decreases with an excessively increased width and excessively decreased intervals.

In view of the relationship between the reduction in resistance loss of the transparent conductive substrate 10 and the transmittance of incident light, the resulting conductive interconnection layer 3 has a width of preferably about 1 to about 1000 μm, and particularly preferably about 10 to about 500 μm; and lines of the conductive interconnection layer 3 are arranged at intervals of preferably about 0.1 to about 100 mm, and particularly preferably about 0.5 to about 50 mm.

The metal oxide layer 30 serves to block the conductive interconnection layer 3 from the after-mentioned electrolyte layer 5 to thereby prevent the reverse electron transfer reaction and the corrosion of the conductive interconnection layer 3.

The metal oxide layer 30 preferably comprises a transparent material having high electron conductivity.

Examples of such materials are In—Sn complex oxide (indium tin oxide; ITO), SnO₂ (including one doped with fluorine or antimony (antimony tin oxide; ATO)), TiO₂, and ZnO. The metal oxide layer 30 preferably comprises at least one selected from these metal oxides.

The thickness of the metal oxide layer 30 is not specifically limited. An excessively thin metal oxide layer 30, however, invites insufficient blocking between the conductive interconnection layer 3 and the electrolyte layer 5. In contrast, an excessively thick metal oxide layer 30 may reduce the optical transmittance. From these viewpoints, the metal oxide layer 30 has a thickness of preferably 0.1 nm to 1 μm and particularly preferably 1 nm to 500 nm.

Where necessary, a predetermined metal oxide material may further be arranged to form a multilayer so as to improve oxidation resistance.

The semiconductor particle layer 4, if used in the after-mentioned photoelectric converter utilizing a photoelectrochemical reaction with the electrolyte layer 5, serves to effectively perform a charge transfer reaction at the interface between these layers.

The semiconductor particle layer 4 is formed by depositing a film of fine semiconductor particles and can comprise, for example, an elementary semiconductor typified by silicon, as well as a compound semiconductor or a compound having a perovskite structure.

These semiconductors are preferably n-type semiconductors containing conduction-band electrons serving as carriers give an anode current upon optical excitation.

Specific examples thereof are TiO₂, ZnO, WO₃, Nb₂O₅, TiSrO₃, and SnO₂, of which anatase TiO₂ is preferred. The material is not limited to these, and each of semiconductor materials can be used alone or in combination as a mixture or compound. The fine semiconductor particles can be in various forms such as particles, tubes, or rods according to necessity.

The particle diameters of fine semiconductor particles constituting the semiconductor particle layer 4 are not specifically limited but are preferably such that the average particle diameter of primary particles is 1 to 200 nm, and particularly preferably 5 to 100 nm.

It is also acceptable that the semiconductor particle layer 4 further comprises two or more different particles having larger particle diameters than the above-specified particle diameter, so as to scatter incident light and to improve the quantum yield. In this case, the large-sized particles to be additionally used preferably have an average particle diameter of 20 to 500 nm.

Although the process is not specifically limited, the semiconductor particle layer 4 is preferably formed by wet deposition of a film of fine semiconductor particles typically in view of properties, convenience, and production cost. Specifically, it is preferably formed by uniformly dispersing powder or sol of fine semiconductor particles in a medium such as water to yield a paste, and applying the paste to a transparent conductive film deposited on the substrate.

The application process is not specifically limited and can be any conventional or known process such as dipping, spraying wire bar coating, spin coating, roller coating, blade coating, or gravure coating. Various wet printing processes such as relief printing, offset printing, gravure printing, intaglio printing, rubber plate printing, and screen printing can also be applied. Alternatively, a process of carrying out electrolytic deposition in a sol containing dispersed fine semiconductor particles.

Anatase titanium oxide, if used for the formation of the semiconductor particle layer 4, can be any of powder, sol, and slurry. Alternatively, the anatase titanium oxide can be particles having predetermined particle diameters prepared according to a conventional procedure such as hydrolysis of a titanium oxide alkoxide.

The secondary aggregation of particles constituting a powder, if used, is preferably solved in advance. Specifically, it is preferred to pulverize the particles typically in a mortar or ball mill in the preparation of a coating composition. In this procedure, acetylacetone, hydrochloric acid, nitric acid, a surfactant, and/or a chelating agent is preferably added so as to avoid re-aggregation of the particles which secondary aggregation has been solved.

Tackifiers may be added for increasing the viscosity. Such tackifiers include polymer tackifiers such as poly(ethylene oxide)s and poly(vinyl alcohol)s; and cellulose tackifiers.

The semiconductor particle layer 4 is allowed to support a sensitizing dye (not shown) for improving the photoelectric conversion efficiency.

The surface area of the resulting semiconductor particle layer 4 is preferably 10 times or more, and more preferably 100 times or more as large as the projected area. The upper limit thereof is not specifically limited, but is generally set at about 1000 times.

In general, with an increasing thickness of the semiconductor particle layer 4, the amount of supported dye per unit projected area increases and thereby the optical trapping ratio increases, but the dispersion distance of doped electron increases and thereby the loss due to charge recombination increases.

Accordingly, the thickness of the semiconductor particle layer 4 is preferably 0.1 to 100 μm, more preferably 1 to 50 μm, and further preferably 3 to 30 μm.

The applied fine semiconductor particles are preferably subjected to firing or burning so as to bring particles into electronic contact with one another and improve the film strength and adhesion with applied surface.

The firing temperature is not specifically limited but is preferably set at 40° C. to 700° C., and more preferably set at 40° C. to 650° C. This is because firing at excessively elevated temperatures may increase the electrical resistance or may invite melting of the film.

The firing time is also not specifically limited, but is practically suitably about 10 minutes to about 10 hours.

Chemical plating using an aqueous titanium tetrachloride solution; electrochemical plating using an aqueous titanium trichloride solution; and/or dipping with a sol of ultrafine semiconductor particles having diameters of 10 nm or less can be carried out after firing, so as to increase the specific surface area of the fine semiconductor particles and increase the necking among fine semiconductor particles.

When a plastic base is used as the transparent base 2, the semiconductor particle layer 4 can be formed by forming a film of a paste containing a binder on the base and carrying out compression bonding.

The sensitizing dye to be supported by the semiconductor particle layer 4 is not specifically limited, as long as it is a material having sensitizing action. Examples thereof include xanthene dyes such as rhodamine B, rose bengal, eosin, and erythrosine; cyanine dyes such as merocyanine, quinocyanine, and kryptocyanine; basic dyes such as phenosafranine, Capri blue, thiocin, and methylene blue; porphyrin compounds such as chlorophyll, zinc porphyrin, and magnesium porphyrin; azo dyes; phthalocyanine compounds; coumarin compounds; a Ru-bipyridine complex compound; anthraquinone dyes; and polycyclic quinone dyes.

The sensitizing dye is preferably a Ru-bipyridine complex compound for high quantum yield. However, it is not specifically limited thereto, and each of the above-mentioned materials can be used alone or in combination.

The sensitizing dye can be adsorbed by the semiconductor particle layer 4 by any process not specifically limited. The adsorption can be carried out, for example, by dissolving the dye in a solvent to form a solution; and dipping a semiconductor electrode bearing the semiconductor particle layer in the solution or applying the solution to the semiconductor electrode. The solvent herein includes, for example, alcohols; nitriles; nitro compounds such as nitromethane; halogenated hydrocarbons; ethers; sulfoxides such as dimethyl sulfoxide; pyrrolidones such as N-methylpyrrolidone; ketones such as 1,3-dimethylimidazolidinone and 3-methyloxazolidinone; esters; carbonic acid esters; hydrocarbons; and water.

The dye solution may further comprise, for example, deoxycholic acid, for reducing intermolecular association. It may also further comprise an ultraviolet absorber.

After the sensitizing dye is absorbed in the above-mentioned manner, the surface of fine semiconductor particles maybe treated with an amine.

Such amines include pyridine, 4-tert-butylpyridine, and polyvinylpyridine. A liquid amine can be used as intact or be dissolved in an organic solvent before use.

Next, the counter electrode 12 will be illustrated.

The counter electrode 12 has a configuration comprising a transparent base 2; and a metal oxide layer 30 and a platinum layer 6 arranged on or above the transparent base 2.

The counter electrode 12 can have a modified configuration, as long as it comprises the metal oxide layer 30 on a surface facing the semiconductor electrode 11. For example, a conductive interconnection layer 3 may be embedded in the transparent base 2, as in the semiconductor electrode 11.

The counter electrode 12 is preferably formed from an electrochemically stable material such as platinum, gold, carbon, or a conductive polymer.

The surface of the counter electrode 12 facing the semiconductor electrode preferably has a fine or minute structure so as to have an increased surface area, in order to improve the catalytic activity in oxidation and reduction. Accordingly, the surface preferably comprises, if platinum is used, platinum black or, if carbon is used, porous carbon.

The platinum black can be formed, for example, by anodic oxidation of platinum or treatment with chloroplatinic acid. The porous carbon can be formed, for example, by sintering of fine carbon particles or firing of an organic polymer.

The counter electrode 12 can also be prepared by arranging, as an interconnection, a metal effectively acting as redox catalyst, such as platinum, or forming a platinum layer 6 which surface has been treated with chloroplatinic acid on the transparent conductive substrate 10.

The electrolyte layer 5 comprises a conventional solution electrolyte containing at least one dissolved substance system (redox system) that reversibly shifts between oxidation/reduction states.

Examples of usable systems include a combination of I₂ and a metal iodide or organic iodide; a combination of Br₂ and a metal bromide or organic bromide; as well as metal complex systems such as ferrocyanate salt/ferricyanate salt system, and ferrocene/ferricinium ion system; sulfur compounds such as poly (sodium sulfide)s, and alkylthiol/alkyl disulfide; viologen dyes; and hydroquinone/quinone system.

Preferred examples of cations for constituting the metal compound are Li, Na, K, Mg, Ca, and Cs, and preferred examples of cations for constituting the organic compound are quaternary ammonium compounds such as tetraalkyl ammoniums, pyridiniums, and imidazoliums, but it is not limited to these, and each of such cations can be used alone or in combination.

Among them, a combination of I₂ with LiI, NaI or a quaternary ammonium compound such as imidazolium iodide is preferred as the electrolyte.

The concentration of the electrolyte salt is preferably 0.05 M to 5 M, and more preferably 0.2 M to 1 M relative to the solvent.

The concentration of I₂ or Br₂ is preferably 0.0005 M to 1 M and more preferably 0.001 to 0.1 M.

Additives such as 4-tert-butylpyridine and carboxylic acids may be added, for improvements in open-circuit voltage and short-circuit current.

Solvents constituting the electrolyte layer 5 include, but are not limited to, water; alcohols; ethers; esters; carbonic acid esters; lactones; carboxylic acid esters; phosphate triesters; heterocyclic compounds; nitriles; ketones such as 1,3-dimethylimidazolidinone and 3-methyloxazolidinone; pyrrolidones such as N-methylpyrrolidone; nitro compounds such as nitromethane; halogenated hydrocarbons; sulfoxides such as dimethyl sulfoxide; sulfolanes; and hydrocarbons. Each of these can be used alone or in combination.

The solvent can also be a liquid of a quaternary ammonium salt of tetraalkyl, pyridinium, or imidazolium, which liquid is ionic at room temperature.

The composition for the electrolyte layer can be used as a gel electrolyte by dissolving a gelatinizing agent, a polymer, or a crosslinkable monomer in the composition, in order to prevent the leakage and evaporation of the electrolyte from the photoelectric converter 1.

The ion conductivity increases but the mechanical strength decreases with an increasing ratio of the electrolyte composition to the gel matrix.

In contrast, the mechanical strength increases but the ion conductivity decreases with an excessively decreasing ratio of the electrolyte composition. Consequently, the amount of the electrolyte composition is preferably 50 percent by weight to 99 percent by weight, and more preferably 80 percent by weight to 97 percent by weight of the gel electrode.

A solid-state photoelectric converter can be realized by dissolving the electrolyte in a polymer with a plasticizer, and removing the plasticizer by evaporation.

The respective components in the photoelectric converter 1 having the above-mentioned configuration are housed in a predetermined case and sealed therein or the entire components including case are sealed with a resin.

The photoelectric converter 1 can be produced by any process not specifically limited, but the electrolyte composition constituting the electrolyte layer 5 must be liquid or gel in the photoelectric converter. When the electrolyte composition is liquid before it is introduced into the converter, the semiconductor electrode 11 supporting the dye, and the counter electrode 12 are sealed so as to face each other but not in contact with each other.

The gap between the semiconductor electrode 11 and the counter electrode 12 is not specifically limited, but is generally set at 1 to 100 μm and preferably set at about 1 to about 50 μm. This is because a photoelectric current decreases due to decreased conductivity if the gap between the electrodes is excessively large.

The sealing process is not specifically limited. The sealing material is preferably one having light resistance, insulating property, and moisture barrier property. Various welding processes, as well as epoxy resins, ultraviolet curable resins, acrylic adhesives, ethylene vinyl acetate (EVA), ionomer resins, ceramic, and thermally adhesive films can be used.

A filling port for charging the solution of the electrolyte composition must be provided. It can be provided at any position other than the semiconductor particle layer bearing the dye, and the corresponding portion of the counter electrode.

The solution can be charged by any process not specifically limited and is preferably charged into the cell through the filling port.

In this case, a process of dropping a few drops of the solution to the filling port and charging the solution as a result of a capillary phenomenon is easy and convenient.

The charging procedure can be carried out under reduced pressure or with heating, where necessary.

After the completion of charging the solution, the solution remained at the filling port is removed, and the filling port is sealed. The sealing process is not specifically limited, and where necessary, the sealing can be carried out by applying a glass plate or a plastic base with a sealing agent to the filling port.

To form a gel electrolyte typically using a polymer or a solid-state electrolyte, a polymer solution containing the electrolyte composition and a plasticizer is cast on the semiconductor electrode bearing the dye, followed by evaporation.

After fully removing the plasticizer, sealing is conducted by the above-mentioned procedure.

The sealing herein is preferably carried out in an inert gas atmosphere or under reduced pressure typically using a vacuum sealer. If necessary, heating and/or pressurizing procedure can be carried out after the sealing, so as to impregnate the semiconductor particle layer with the electrolyte sufficiently.

The photoelectric converter 1 can be formed into any of various shapes not specifically limited, according to the use thereof.

The photoelectric converter 1 operates as follows.

Specifically, light enters through the transparent base 2 constituting the semiconductor electrode 11 and excites the dye carried on the surface of the semiconductor particle layer 4, and the excited dye rapidly turns over an electron to the semiconductor particle layer 4.

The dye which has lost the electron receives another electron from an ion in the electrolyte layer 5 as a carrier transfer layer.

The molecule which has turned over the electron receives still another electron from the metal oxide layer 30 constituting the counter electrode 12. Thus, a current passes through between the two electrodes.

In the above-mentioned embodiments, a dye-sensitized solar cell is taken as an example of the photoelectric converter 1, but the present invention can also be applied to other solar cells than dye-sensitized solar cells, as well as to photoelectric converters other than solar cells. It should be noted that various modifications and variations are possible unless departing from the spirit and scope of the present invention.

### EXAMPLES

### Example 1

Initially, a TiO₂ paste for constituting a semiconductor particle layer 4 was prepared.

The TiO₂ paste was prepared according to a procedure with reference to “Latest Technologies for Dye-sensitizing Solar Cells” (CMC Publishing Co., Ltd.).

Titanium isopropoxide (125 ml) was gradually added dropwise to 750 ml of a 0.1 M aqueous nitric acid solution at room temperature with stirring. After the completion of dropwise addition, the mixture was transferred to a thermostat at 80° C. and was stirred for 8 hours to thereby yield a whitish semitransparent sol. This sol was gradually cooled to room temperature, filtrated through a glass filter, and measured up to 700 ml.

The above-prepared sol was transferred to an autoclave and subjected to hydrothermal treatment at 220° C. for 12 hours. Thereafter, dispersion was conducted by ultrasonic treatment for one hour. The dispersed sol was concentrated at 40° C. on an evaporator to have a TiO₂ content of 20 percent by weight.

The concentrated sol was combined with 20 percent by weight vs. TiO₂ of polyethylene glycol having a molecular weight of 50×10⁴ and 30 percent by weight vs. TiO₂ of anatase TiO₂ having a particle diameter of 200 nm, the mixture was homogenously mixed using a stirring deaerator and thereby yielded a tackified TiO₂ paste.

Next, a transparent conductive substrate 10 was prepared.

Initially, a quartz plate 25 mm wide, 60 mm long, and 1.1 mm thick was prepared as a transparent base 2, on which eleven trenches having a depth of 20 μm and a width of 100 μm were formed at 2-mm intervals in parallel with the longitudinal direction using a slicing machine.

The transparent base 2 bearing the trenches 3h thus formed was washed, and a film of nickel was formed by electroless plating to a thickness of 25 μm on the surface of the transparent base bearing the trenches.

Next, the plated surface was optically polished, nickel deposited on the transparent base was removed to thereby yield a conductive interconnection layer 3 bearing nickel only inside the trenches.

Washing was then carried out, films of ITO to a thickness of 500 nm and of ATO to a thickness of 50 nm were deposited on the surface bearing the conductive interconnection layer 3 by sputtering to thereby yield a metal oxide layer 30.

Next, annealing was conducted at 400° C. for 15 minutes to thereby yield a transparent conductive substrate 10.

The above-prepared TiO₂ paste was applied to the transparent conductive substrate 10 to a size of 20 mm wide and 50 mm long by blade coating at a gap of 200 μm, and the applied TiO₂ film was sintered by holding the same at 450° C. for 30 minutes.

To the sintered TiO₂ film was added dropwise a 0.1 M-aqueous TiCl₄ solution, the article was held at room temperature for 15 hours, washed, and fired at 450° C. for 30 minutes. The resulting TiO₂ sintered compact was irradiated with ultraviolet radiation for 30 minutes using an ultraviolet irradiator so as to remove impurities and to improve the activity of the sintered compact. Thus, a semiconductor particle layer 4 was prepared.

Next, the semiconductor particle layer 4 was allowed to support a dye and thereby yielded a semiconductor electrode.

Specifically, the semiconductor particle layer 4 was immersed in a solution of 0.5 mM cis-bis(isothiocyanato)-N,N-bis(2,2′-dipyridyl-4,4′-dicarboxylic acid)-ruthenium(II) ditetrabutylammonium salt and 20 mM deoxycholic acid in a 1:1 (by weight) mixed solvent of tert-butyl alcohol and acetonitrile at 80° C. for 24 hours to support the dye, to thereby yield the semiconductor electrode.

The above-prepared semiconductor electrode was sequentially washed with an acetonitrile solution of 4-tert-butylpyridine and acetonitrile in this order and was dried in a dark place.

Next, a counter electrode 12 was prepared.

The counter electrode was prepared by sequentially depositing a film of chromium 50 nm thick and a film of platinum 100 nm thick onto a fluorine-doped conductive glass substrate (surface resistivity (sheet resistance): 10 ohms per square) having a 0.5-mm filling port by sputtering; applying a solution of chloroplatinic acid in isopropyl alcohol (IPA) thereonto by spray coating; and carrying out heating at 385° C. for 15 minutes.

A photoelectric converter 1 was prepared using the above-prepared semiconductor electrode 11 and counter electrode 12.

Specifically, the semiconductor electrode and the counter electrode were arranged so that the TiO₂ film of the semiconductor electrode and the platinum layer of the counter electrode face each other, and the circumference of the two electrodes was sealed with an ionomer resin film 30 μm thick and a silicon adhesive.

Next, an electrolyte composition was prepared by dissolving 0.04 g of sodium iodide (NaI), 0.479 g of 1-propyl-2,3-dimethylimidazolium iodide, 0.0381 g of iodine (I₂), and 0.2 g of 4-tert-butylpyridine in 3 g of methoxyacetonitrile.

The electrolyte composition was charged into between the electrodes using a delivery pump, and the pressure was reduced to remove inside bubbles. The filling port was sealed with an ionomer resin film, a silicon adhesive, and a glass base, and the target photoelectric converter was obtained.

### Examples 2 to 4

A series of photoelectric converters 1 was prepared under the conditions of Example 1, except for using materials for the conductive interconnection layer 3 shown in Table 1 below.

### Examples 5 to 7

A series of photoelectric converters 1 was prepared under the conditions of Example 1, except for forming the conductive interconnection layer 3 by printing using commercially available pastes of the materials shown in Table 1 below.

### Example 8

A photoelectric converter 1 was prepared under the conditions of Example 1, except for forming the conductive interconnection layer 3 by welding using an ultrasonic soldering device.

### Comparative Example 1

A photoelectric converter 1 was prepared under the conditions of Example 1, except for forming no conductive interconnection layer 3.

### Comparative Example 2

A photoelectric converter 1 was prepared under the conditions of Example 1, except for forming no metal oxide layer 30.

### Comparative Example 3

A photoelectric converter 1 was prepared under the conditions of Example 1, except for using a commercially available nickel paste as a material for the formation of the conductive interconnection layer; forming no trench in the transparent base 2; and forming a conductive interconnection layer on the surface of the transparent base by printing.

### Comparative Examples 4 and 5

A series of photoelectric converters 1 was prepared under the conditions of Example 1, except for using the commercially available pastes of materials shown in Table 1 below as a material for the formation of the conductive interconnection layer; forming no trench in the transparent base 2; and forming a conductive interconnection layer on the surface of the transparent base by printing.

Table 1 shows the materials and forming processes for the conductive interconnection layer, differences in height or depth with the transparent base plane, contact angles at the side wall, and materials and thicknesses of the metal oxide layer of the photoelectric converters according to Examples 1 to 8 and Comparative Examples 1 to 5.

TABLE 1

| | | Difference in | |
|---|---|---|---|
| | | height or depth of | |
| | Conductive | embedded conductive | |
| | interconnection layer | interconnection layer | Metal oxide layer |
| Example 1 | Ni (plating) | −3 μm | ITO 500 nm/ATO 50 nm |
| Example 2 | Ag (plating) | −5 μm | ITO 500 nm/ATO 50 nm |
| Example 3 | Cu (plating) | −6 μm | ITO 500 nm/ATO 50 nm |
| Example 4 | Pt (plating) | −6 μm | ITO 500 nm/ATO 50 nm |
| Example 5 | Ni (paste) | +5 μm | ITO 500 nm/ATO 50 nm |
| Example 6 | Ag (paste) | +2 μm | ITO 500 nm/ATO 50 nm |
| Example 7 | Al (paste) | +2 μm | ITO 500 nm/ATO 50 nm |
| Example 8 | Soldering | +1 μm | ITO 500 nm/ATO 50 nm |
| Com. Ex. 1 | none | — | ITO 500 nm/ATO 50 nm |
| Com. Ex. 2 | Ni (plating) | −3 μm | none |
| Com. Ex. 3 | Ni (paste) (difference in | not embedded | ITO 500 nm/ATO 50 nm |
| | height 23 μm, contact | | |
| | angle 82°) | | |
| Com. Ex. 4 | Ag (paste) (difference in | not embedded | ITO 500 nm/ATO 50 nm |
| | height 30 μm, contact | | |
| | angle 85°) | | |
| Com. Ex. 5 | Al (paste) (difference in | not embedded | ITO 500 nm/ATO 50 nm |
| | height 25 μm, contact | | |
| | angle 79°) | | |

The above-prepared photoelectric converters according to Examples 1 to 8 and Comparative Examples 1 to 5 were evaluated on fill factor and photoelectric conversion efficiency, and their conductive interconnection layers were visually observed and evaluated immediately after their preparation and after storage for one month.

The fill factor and photoelectric conversion efficiency were determined upon irradiation with artificial sunlight (AM 1.5, 100 mW/cm²). During the storage for one month, the photoelectric converters were irradiated with ultraviolet radiation at room temperature.

In the visual observation of the conductive interconnection layer, a sample showing no change was evaluated as “Good”, one showing partial dissolution was evaluated as “Fair”, and one showing full dissolution was evaluated as “Failure”.

The results of these evaluations are shown in following Table 2.

TABLE 2

| | Immediately after preparation | | | After one month | | |
|---|---|---|---|---|---|---|
| | | Photoelectric | | | Photoelectric | |
| | | conversion | Visual | | conversion | Visual |
| | Fill factor | efficiency | observation | Fill factor | efficiency | observation |
| Example 1 | 72.3% | 9.1% | Good | 72.0% | 8.9% | Good |
| Example 2 | 73.5% | 9.2% | Good | 73.2% | 9.0% | Good |
| Example 3 | 73.1% | 9.0% | Good | 73.0% | 8.7% | Good |
| Example 4 | 68.1% | 8.7% | Good | 68.2% | 8.4% | Good |
| Example 5 | 65.3% | 8.4% | Good | 65.5% | 8.3% | Good |
| Example 6 | 69.1% | 8.9% | Good | 68.7% | 8.5% | Good |
| Example 7 | 68.8% | 8.8% | Good | 67.9% | 8.5% | Good |
| Example 8 | 70.5% | 7.9% | Good | 69.3% | 7.8% | Good |
| Com. Ex. 1 | 23.3% | 0.1% | Good | 23.3% | 0.1% | Good |
| Com. Ex. 2 | 2.1% | No power | Good | 2.0% | No power | Fair |
| | | generation | | | generation | |
| Com. Ex. 3 | 61.3% | 6.2% | Good | 30.9% | 3.5% | Fair |
| Com. Ex. 4 | 55.3% | 5.5% | Good | 20.3% | 0.1% | Failure |
| Com. Ex. 5 | 45.2% | 4.5% | Good | 21.2% | 0.2% | Failure |

Description of symbols in “Visual observation”; Good: Good and no change, Fair: Partially dissolved, Failure: Fully dissolved

As is obvious from a comparison between the evaluations of the samples according to Example 1 to 8 and the sample according to Comparative Example 1 in Table 2, the photoelectric conversion efficiency can be dramatically effectively improved by arranging the conductive interconnection layer 3 in the semiconductor electrode.

The photoelectric converter according to Comparative Example 2 having no metal oxide layer 30 cannot exhibit practically sufficient functions.

The evaluations on the samples according to Examples 1 to 8 show that the corrosion of the conductive interconnection layer 3 can be avoided and an excellent photoelectric conversion efficiency can be maintained both immediately after preparation and after long-term storage, by embedding the conductive interconnection layer 3 in the transparent base 2 of the semiconductor electrode and by controlling the difference in height or depth between the interconnection layer 3 and the transparent base 2 within the range of −10 μm to 10 μm.

In contrast, the samples according to Comparative Examples 3 to 5 having the conductive interconnection layer 3 being not embedded but arranged on the transparent base 2 cannot provide a practically sufficient photoelectric conversion efficiency typically after the long-term storage, because the conductive interconnection layer 3 is not sufficiently covered by the upper layer metal oxide layer 30, is thereby corroded by the electrolyte solution of the electrolyte layer 5, and is dissolved typically after the long-term storage.

1-4. (canceled)

5. A method of forming a photoelectric converter, comprising:
etching a transparent base to form one or more trenches;
forming a conductive film in the one or more trenches;
depositing a layer of indium tin oxide (ITO) on the transparent base and the conductive film; and
depositing, by sputtering, a layer of antimony tin oxide (ATO) on the layer of ITO.

6. The method of claim 5, wherein forming the conductive film is performed using electroless plating.

7. The method of claim 5, wherein depositing the layer of ITO comprises depositing approximately 500 nm of ITO and wherein depositing the layer of ATO comprises depositing approximately 50 nm of ATO.

8. The method of claim 5, further comprising performing an annealing step after deposition of the layer of ATO.
